(19) United States
(12) Patent Application Publication
(10) Pub. No.: US 2006/0046211 A1
(43) Pub. Date: Mar. 2, 2006

(54) Effectively water-free immersion lithography

(75) Inventors: Chi-Wen Liu, Hsinchu (TW); Horng-Huei Tseng, Hsinchu (TW); Chin-Hsiang Lin, Hsinchu (TW)

Correspondence Address: DUANE MORRIS LLP;IP DEPARTMENT (TSMC), 30 SOUTH 17TH STREET, PHILADELPHIA, PA, 19103-4196, US

(73) Assignee: Taiwan Semiconductor Manufacturing Co., Ltd.

(21) Appl. No.: 10/928,455

(22) Filed: Aug. 27, 2004

(51) Int. Cl. G03B 27/52; G03F 7/20

(52) U.S. Cl. 430/395; 355/30

(57) ABSTRACT

A method and system is disclosed for conducting immersion photolithography. The system includes at least one lens for transmitting a predetermined radiation on a predetermined substrate with a distance between the lens and the substrate shorter than a predetermined threshold, and a fluid volume in contact with the lens on its first end, and with the substrate on its second end, wherein the fluid volume is an effectively water-free fluid.

### BACKGROUND

The present invention relates generally to integrated circuits, and more particularly, to a method and system of enabling the use of 193-nm light, or sub-193 nm light, and its corresponding photoresist in immersion lithography.

The production of semiconductor integrated circuits (ICs) involves the repeated application of lithography techniques by using sophisticated projection optical systems. An image of each structural level of an IC is projected onto a photoresist layer that is coated on a semiconductor wafer. Each image typically contains one or more structural levels of the IC. After the photoresist is developed, the remaining pattern protects portions of the wafer from a selected physical or chemical reaction such as etching. Other reactions follow, after which the sequence may be repeated to fabricate devices on a chip. With each new generation of processing technology, printed images require finer and finer geometries and, therefore, shorter and shorter wavelength of light.

The production of ICs requires printed layout images at an extremely fine resolution, but this resolution is limited by, among other things, the wavelength of the projected light used. In today's lithography techniques, the fine geometries require the use of light with a wavelength at least as short as 193 nanometers. Finer geometries may be required in newer, more compact technologies. To achieve the printing of finer geometries, one option is to use an immersion lithography system, which includes a water-immersion objective lens for projecting images on the wafer. The short space between the objective lens and the substrate is filled with a particular water based fluid, so that the light path does not include air, with its low index of refraction. Illuminating light travels from the objective lens into the fluid, instead of air, and then onto the substrate, from where it is reflected backward. As light emerges from the glass lens and into the fluid, it is refracted less from the optical axis than it would have been, if it had emerged from the glass lens into air.

The optical path between the final lens and the semiconductor wafer, which may be coated with a photoresist layer is critical. The difference between the index of refraction of the final lens and that of the fluid, and the angle at which the light approaches the interface, determine the angle of refraction at any point on the lens. Immersion lithography replaces the air with de-ionized water, which has an index of refraction that is higher than that of air. The result is less deviation of the light from the optical axis. The object appears closer, and the resolution is improved. In addition, when a light with a wavelength as short as 193 nm is used, a particular type of photoresist may be required. Some particular type of photoresist, such as Shiply K98 and Sumitomo PAR 101, may react with water.

Desirable in the art of immersion lithography designs are additional methods that enable the use of 193-nm light for semiconductor manufacturing.

### SUMMARY

In view of the foregoing, the present invention provides a system and method employing an effectively water-free fluid in immersion lithography in sub-193-nanometer lithography.

In two embodiments of the present invention, a shower system and a bath system are presented. Both systems include at least one lens for transmitting a predetermined radiation on a predetermined substrate with a distance between the lens and the substrate shorter than a predetermined threshold, and a fluid volume in contact with the lens on its first end, and with the substrate on its second end, wherein the fluid volume is an effectively water-free fluid.

The construction and method of operation of the invention, however, together with additional objects and advantages thereof will be best understood from the following description of specific embodiments when read in connection with the accompanying drawings.

### BRIEF DESCRIPTION OF THE DRAWINGS

FIG. 1 illustrates a setup of an immersion optical projection system, in accordance with a first embodiment of the present invention.

FIG. 2 illustrates a setup of an immersion optical projection system, in accordance with a second embodiment of the present invention.

### DESCRIPTION

Immersion lithography systems have been introduced for use in the projection printing of a circuit layout image onto a photoresist layer on a semiconductor wafer. Such systems are designed for use with pure or de-ionized water. The effect of the immersion is to achieve resolution as if the exposing light wavelength was about a lower wavelength instead of the resolution achieved in air with an actual higher wavelength. Any immersion lens must keep the immersion fluid outside itself, and the optical lens is appropriately designed for immersion. Accommodation must be made for handling fluid in a thin layer, typically, 2-mm thick, between the lens and the semiconductor substrate across a semiconductor wafer that may be 6″, 8″, 12″, or larger dimension than 12″ in diameter.

Other than searching for a better fluid to be used between the lens and the wafer substrate, an improved fluid is needed to deal with a difficulty that has become apparent which is that the particular types of photoresist that are most useful at the desirable exposure wavelength of about 193 nm, or less, are adversely affected by pure or de-ionized water. For example, water-soluble contents in photoresist may dissolve in the pure or de-ionized water, which damages the photoresist, reduces the light transmittance in the pure or de-ionized water, and contaminates the lens.

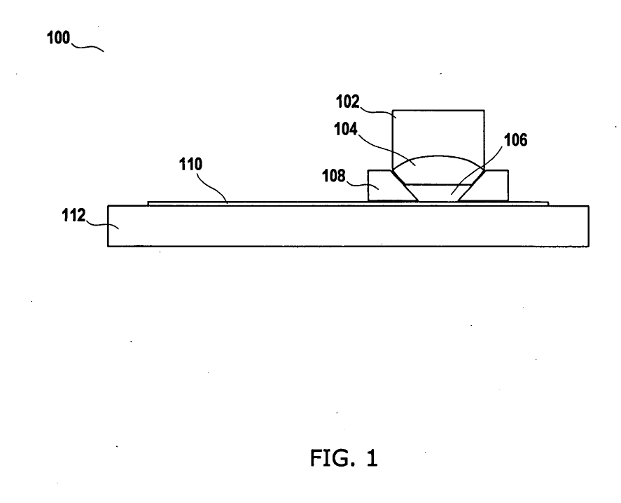

FIG. 1 illustrates a setup 100 of an immersion optical projection system, in accordance with a first embodiment of the present invention. This is a shower configuration. A barrel 102 supports a final lens 104. A specialty fluid 106 is contained between the lens 104 and a containment bezel 108. The specialty fluid 106 is supplied externally and escapes slowly through the narrow separation between the containment bezel 108, and a semiconductor wafer 110 that is to be pattern-exposed. The semiconductor wafer 110 is locked to a scanning stage 112 for the duration of the exposure process. The scanning stage 112 moves, stepwise, within its own plane that is horizontal, here shown in cross section, and perpendicular to the page. The specialty fluid 106 may be perfluoropolyether (PFPE) or cyclo-octane. The scanning stage 112 presents the semiconductor wafer 110 with a photoresist coating, not shown, for pattern exposure by radiation such as light of a particular wavelength from the final lens 104. Light from the final lens 104 traverses a narrow space that is filled with the specialty fluid 106, instead of air or water, between the final lens 104, and the photo resist coating, not shown, on the semiconductor wafer 110.

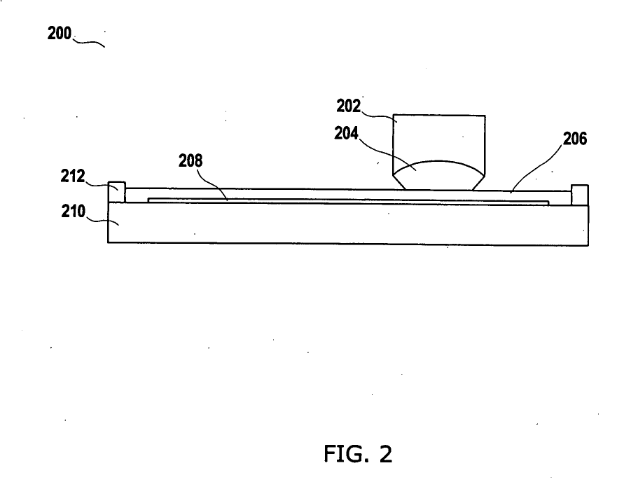

FIG. 2 illustrates a setup 200 of an immersion optical projection system, in accordance with a second embodiment of the present invention. This is a bath configuration. A barrel 202 supports a final lens 204. A specialty fluid 206 is contained in a layer between the final lens 204, and a semiconductor wafer 208 that is to be pattern-exposed. The semiconductor wafer 208 is locked to a scanning stage 210 for the duration of the exposure process. The scanning stage 210 is surrounded by a wall 212 that encloses a layer of the specialty fluid 206, as if in a bathtub. The scanning stage moves stepwise within its own plane that is horizontal, here shown in cross section, and perpendicular to the page. The specialty fluid 206 may be perfluoropolyether (PFPE), or cyclo-octane. The scanning stage 210 presents the semiconductor wafer 208 with a photoresist coating, not shown, for pattern exposure by radiation such as light of a particular wavelength from the final lens 204. Light from the final lens 204 traverses a narrow space that is filled with the specialty fluid 206 instead of air or water between the final lens 204 and the photoresist coating, not shown, on the semiconductor wafer 208. The fill and drain mechanisms for the bath are not shown.

In the above embodiments of the invention, an immersion photolithography method and a system are proposed to replace pure, or de-ionized water, with an effectively water-free fluid volume that is in contact with the lens on its upper, or first end, and with the substrate on its lower, or second end. The system includes a radiation source that provides electromagnetic radiation of 193 nm, or less, and at least one lens that transmits at least that selected predominant wavelength. The shorter wavelengths that may be used include 157 nm, or less. The fluid volume is chemically compatible with the selected product substrate, which may be a topmost photoresist layer of a semiconductor wafer. The fluid is preferred to have no water in it, but it may still contain a small portion of water for some embodiments. Although the fluid may still contain some water, it is deemed as “effectively water-free” when the water content is below 25 percent of the total volume, and in some cases, it is below 20 percent. The relatively small concentration of the water in the fluid helps to produce a better refraction index. Examples of selected, water-free fluid volumes include a Perfluorinated Polyether based fluid, such as perfluoropolyether (PFPE), made by E.I. DuPont de Nemours and Company, or a cyclo-octane based fluid. The light absorption rate of any one of such fluid volumes is preferred to be less than 0.1%, even when water is used. Also, a selected fluid volume typically has a viscosity value less than that of pure or de-ionized water. In addition, in order to assure the wetting of all surfaces in the optical path, for maximum and proper light transmission, and to avoid the attachment to any surface of bubbles (that would optically distort a projected image, the fluid volume may contain surfactants. In such case, the molar concentration of hydroxyl ions, in the fluid volume, may be more than 10⁻⁷ mole per liter.

Fresh, filtered, fluid must be constantly introduced to wash away contaminants. Filtering, or a degas module, is also necessary to remove bubbles that could distort imaging. The temperature of the fluid and the staging must be controlled precisely so that the thermal condition of the fluid remains the same.

In this invention, an effectively water-free fluid is used in immersion lithography without degrading the photoresist used for appropriate sub-193-nanometer lithography. The effectively water-free fluid facilitates the optical purpose without chemically or physically reacting with the photoresist coating on the semiconductor wafer.

The above illustration provides many different embodiments or embodiments for implementing different features of the invention. Specific embodiments of components and processes are described to help clarify the invention. These are, of course, merely embodiments, and are not intended to limit the invention from that described in the claims.

Although the invention is illustrated and described herein as embodied in one or more specific examples, it is nevertheless not intended to be limited to the details shown, since various modifications and structural changes may be made therein without departing from the spirit of the invention, and within the scope and range of equivalents of the claims. Accordingly, it is appropriate that the appended claims be construed broadly, and in a manner consistent with the scope of the invention, as set forth in the following claims.

What is claimed is:

1. A photolithography system comprising:
at least one lens for transmitting a predetermined radiation on a predetermined substrate with a distance between the lens and the substrate shorter than 2 mm; and
a fluid volume in contact with the lens on its first end and with the substrate on its second end,
wherein the fluid volume is an effectively water-free fluid.

2. The system of claim 1 further comprising a radiation source providing an electromagnetic radiation with a wavelength of about 193 nm, or less.

3. The system of claim 1 further comprising a radiation source providing an electromagnetic radiation with a wavelength of about 157 nm, or less.

4. The system of claim 1 wherein the fluid volume has a light absorption rate less than 0.1%.

5. The system of claim 1 wherein the fluid volume contains less than 20 percent of water.

6. The system of claim 1 wherein the fluid volume is temperature controlled.

7. The system of claim 1 wherein the fluid volume has a viscosity less than that of pure water.

8. The system of claim 1 wherein the fluid volume contains cyclo-octane.

9. The system of claim 1 wherein the fluid volume contains surfactant.

10. The system of claim 1 wherein the fluid volume contains Perfluorinated Polyether.

11. The system of claim 1 further comprising a degas module for removing undesired bubbles.

12. The system of claim 1 wherein the substrate is a topmost photoresist layer of a wafer.

13. The system of claim 1 wherein the fluid volume contains no water.

14. A photolithography system comprising:
a radiation source providing an electromagnetic radiation with a wavelength of about 193 nm, or less;
at least one lens for transmitting a predetermined radiation from the radiation source on a predetermined substrate; and
a fluid volume in contact with the lens on its first end and with the substrate on its second end,
wherein a distance between the lens and the substrate is shorter than 2 mm and the fluid volume has a light absorption rate less than 0.1%.

15. The system of claim 14 wherein the fluid volume contains less than 25 percent of water.

16. The system of claim 14 wherein the fluid volume has a viscosity less than that of pure water.

17. The system of claim 14 wherein the fluid volume is a cyclo-octane based fluid.

18. The system of claim 14 wherein the fluid volume contains surfactant.

19. The system of claim 14 wherein the fluid volume is a Perfluorinated Polyether based fluid.

20. The system of claim 14 further comprising a degas module for removing undesired bubbles in the fluid volume.

21. The system of claim 14 wherein the substrate is a topmost photoresist layer of a wafer.

22. The system of claim 14 wherein the fluid volume contains no water.

23. A photolithography method comprising the steps of:
providing an electromagnetic radiation with a wavelength of about 193 nm or less;
transmitting a predetermined radiation through at least one lens on a predetermined substrate; and
transmitting the radiation through a fluid volume in contact with the lens on its first end and with the substrate on its second end,
wherein a distance between the lens and the substrate is shorter than 2 mm and the fluid volume has less than 25 percent of water.

24. The method of claim 23 wherein the fluid volume has a light absorption rate less than 0.1%.

25. The method of claim 23 wherein the fluid volume is a cyclo-octane based fluid.

26. The method of claim 23 wherein the fluid volume is a Perfluorinated Polyether based fluid.
